(19) United States
(12) Patent Application Publication
(10) Pub. No.: US 2011/0005587 A1
(43) Pub. Date: Jan. 13, 2011

(54) MADE TO ELEMENTS CAPABLE OF COLLECTING LIGHT

(75) Inventors: Stephane Auvray, Suresnes (FR); Nikolas Janke, Herzogenrath (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: SAINT-GOBAIN GLASS FRANCE, COURBEVOIE (FR)

(21) Appl. No.: 12/681,679

(22) PCT Filed: Sep. 8, 2008
(86) PCT No.: PCT/FR08/51600

§ 371 Date: Sep. 30, 2010

(30) Foreign Application Priority Data
Oct. 5, 2007 (FR) 0758090

(51) Int. Cl. H01L 31/0216; C23C 14/34

(52) U.S. Cl. 136/256; 204/192.12

(57) ABSTRACT

A substrate (1) having a glass function that contains alkali metals comprising a first main face intended to be combined with a layer based on an absorbent material, in particular of chalcopyrite type, and a second main face is characterized in that it has, on at least one surface portion of the second main face, at least one alkali-metal barrier layer (9).

The present invention relates to improvements made to elements capable of collecting light or, more generally, to any electronic device such as a solar cell based on semiconductor materials.

It is known that elements capable of collecting light of the thin-film photovoltaic solar cell type comprise a layer of absorbent agent, at least one electrode positioned on the light incidence side based on a metallic material and a rear electrode based on a metallic material, this rear electrode possibly being relatively thick and opaque. It should be essentially characterized by a surface electrical resistance as low as possible and good adhesion to the layer of absorber and, where appropriate, to the substrate.

Ternary chalcopyrite compounds, which may act as absorber, generally contain copper, indium and selenium. Layers of such absorbent agent are referred to as CISe₂ layers. The layer of absorbent agent may also contain gallium (e.g. Cu(In,Ga)Se₂ or CuGaSe₂), aluminum (e.g. Cu(In,Al)Se₂) or sulfur (e.g. CuIn(Se,S)). They are denoted in general, and hereafter, by the term chalcopyrite absorbent agent layers.

In the context of this chalcopyrite absorbent agent system, the rear electrodes are most of the time manufactured based on molybdenum.

However, high performance of this system can only be achieved by a rigorous control of crystalline growth of the absorbent agent layer, and of its chemical composition.

Furthermore, it is known that among all the factors that contribute thereto, the presence of sodium (Na) on the Mo layer is a key parameter which favors the crystallization of the chalcopyrite absorbent agents. Its presence in a controlled amount makes it possible to reduce the density of absorber defects and to increase its conductivity.

Since the substrate having a glass function contains alkali metals, generally based on soda-lime-silica glass, it naturally constitutes a sodium reservoir. Under the effect of the process for manufacturing absorbent agent layers, generally carried out at high temperature, the alkali metals will migrate through the substrate, from the molybdenum-based rear electrode toward the layer of absorbent agent, in particular of chalcopyrite type. The molybdenum layer allows the sodium to diffuse freely from the substrate toward the upper active layers under the effect of thermal annealing. This Mo layer has, all the same, the drawback of only allowing a partial and not very precise control of the amount of Na that migrates at the Mo/CIGSe₂ interface.

According to one embodiment variant, the absorbent agent layer is deposited, at high temperature, on the molybdenum-based layer, which is separated from the substrate by means of a barrier layer based on Si nitrides, oxides or oxynitrides, or on aluminum oxides or oxynitrides. This barrier layer makes it possible to block the diffusion of the sodium resulting from the diffusion within the substrate toward the upper active layers deposited on the Mo.

Although adding an additional step to the manufacturing process, the latter solution offers the possibility of very precisely metering the amount of Na deposited on the Mo layer by using an external source (e.g. NaF, Na₂O₂, Na₂Se).

The process of manufacturing molybdenum-based electrodes is a continuous process, which implies that the thus coated substrates are stored in a stack on trestles before their subsequent use in a repeat process during which the layer based on absorbent material will be deposited on the surface of the molybdenum electrode.

During the phases when the substrates are stored in racks, the molybdenum layer therefore faces the glass substrate opposite. This sodium-rich face is capable of contaminating the molybdenum face and of enriching it over time. This uncontrolled doping mechanism may lead to a drift in the manufacturing processes during the repeat molybdenum deposition phase.

The present invention therefore aims to overcome these drawbacks by providing a substrate having a glass function for which the diffusion of sodium is controlled.

For this purpose, the substrate having a glass function that contains alkali metals comprising a first main face intended to be combined with a layer based on an absorbent material, of chalcopyrite type, and a second main face is characterized in that it has, on at least one surface portion of the second main face, at least one alkali-metal barrier layer.

In preferred embodiments of the invention, one or more of the following arrangements may optionally be furthermore employed:
it has, on at least one surface portion of the first main face, at least one alkali-metal barrier layer;
the barrier layer is based on a dielectric;
the dielectric is based on silicon nitrides, oxides or oxynitrides, or on aluminum nitrides, oxides or oxynitrides, used alone or as a mixture;
the thickness of the barrier layer is between 3 and 200 nm, preferably between 20 and 100 nm, and substantially in the vicinity of 50 nm;
the barrier layer is based on silicon nitride;
the layer based on silicon nitride is substoichiometric; and
the layer based on silicon nitride is superstoichiometric.

According to another aspect, the invention also relates to an element capable of collecting light that uses at least one substrate as described previously.

In preferred embodiments of the invention, one or more of the following arrangements may optionally be furthermore employed:
element capable of collecting light, comprising a first substrate having a glass function and a second substrate having a glass function, said substrates sandwiching between two electrode-forming conductive layers at least one functional layer based on a chalcopyrite absorbent agent material for converting light energy into electrical energy, characterized in that one at least of the substrates is based on alkali metals and has, on one of its main faces, at least one alkali-metal barrier layer;
at least one surface portion of the main face of the substrate that is not coated with the barrier layer comprises a molybdenum-based conductive layer;
an alkali-metal barrier layer is interposed between the conductive layer and the main face of the substrate;
the alkali-metal barrier layer is based on a dielectric;
the dielectric is based on silicon nitrides, oxides or oxynitrides, or on aluminum nitrides, oxides or oxynitrides, used alone or as a mixture; and
the thickness of the barrier layer is between 3 and 200 nm, preferably between 20 and 100 nm, and substantially in the vicinity of 50 nm.

According to another aspect, the invention also relates to a process for manufacturing a substrate as described previously, which is characterized in that the barrier layer and the electrically conductive layer or a second barrier layer are deposited using a “sputter up” and “sputter down” magnetron sputtering process.

Other features, details and advantages of the present invention will become more clearly apparent on reading the following description, given by way of illustration but implying no limitation, with reference to the appended figures in which:

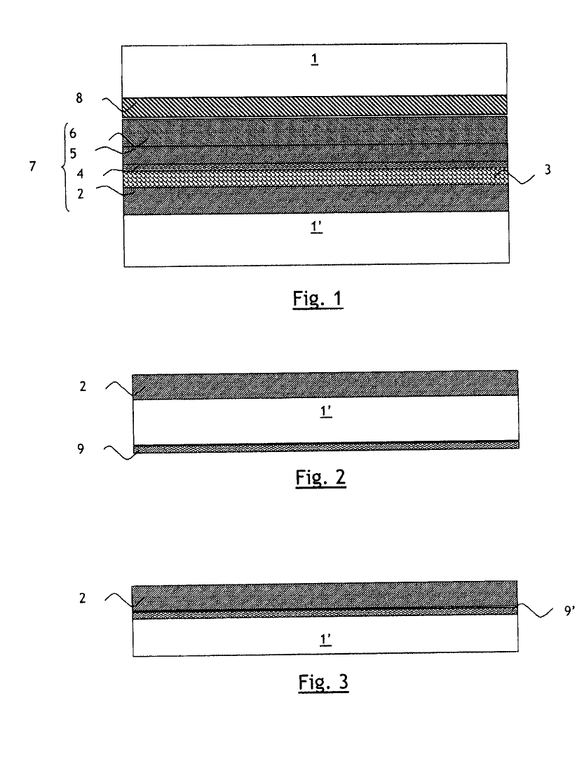

FIG. 1 is a schematic view of an element capable of collecting light according to the invention;

FIG. 2 is a schematic view of a substrate according to a first embodiment, the barrier layer being deposited on the tin face of said substrate;

FIG. 3 is a schematic view of a substrate according to a second embodiment, the barrier layer being deposited on the air face of said substrate; at the interface between the glass and the conductive layer; and

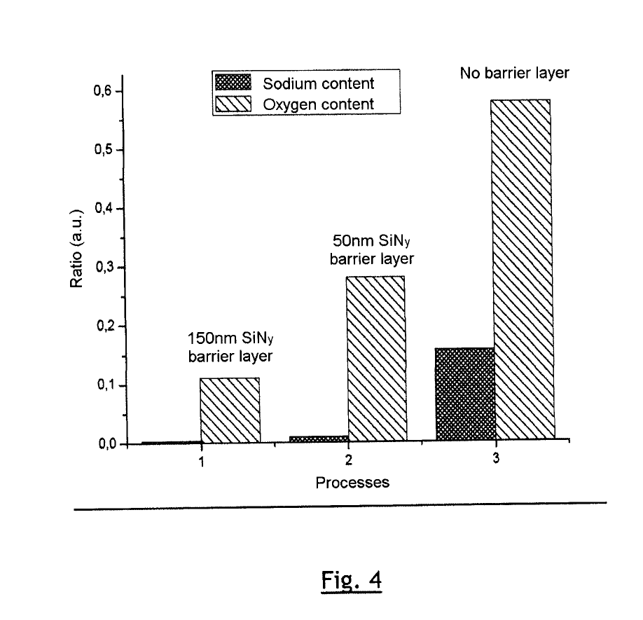

FIG. 4 is a graph showing the change in the content of oxygen and of sodium in the functional layer, as a function of various thicknesses of the barrier layer.

FIG. 1 shows an element capable of collecting light (a solar or photovoltaic cell).

The transparent substrate 1 having a glass function may for example be made entirely of glass containing alkali metals such as a soda-lime-silica glass. It may also be made of a thermoplastic polymer, such as a polyurethane, a polycarbonate or a polymethyl methacrylate.

Most of the mass (i.e. for at least 98% by weight) or even all of the substrate having a glass function consists of material(s) exhibiting the best possible transparency and preferably having a linear absorption of less than 0.01 mm⁻¹ in that part of the spectrum useful for the application (solar module), generally the spectrum ranging from 380 to 1200 nm.

The substrate 1 according to the invention may have a total thickness ranging from 0.5 to 10 mm when this is used as a protective plate for a photovoltaic cell produced from various (CIS, CIGS, CIGSe₂, etc.) chalcopyrite technologies or as a support substrate 1′ intended to receive the whole of the functional stack. When the substrate is used as a protective plate, it may be advantageous to subject this plate to a heat treatment (for example of the toughening type) when it is made of glass.

Conventionally, A defines the front face of the substrate, which is turned towards the light rays (this is the external face) and B defines the rear face of the substrate, turned towards the rest of the layers of the solar module (this is the internal face).

The B face of the substrate 1′ is coated with a first conductive layer 2 having to serve as an electrode. The functional layer 3 based on a chalcopyrite absorbent agent is deposited on this electrode 2. When this is a functional layer 3 based for example on CIS, CIGS or CIGSe₂, it is preferable for the interface between the functional layer 3 and the electrode 2 to be based on molybdenum. A conductive layer meeting these requirements is described in European Patent Application EP 1 356 528.

The layer 3 of chalcopyrite absorbent agent is coated with a thin layer 4 of cadmium sulfide (CdS) making it possible to create, with the chalcopyrite layer 3, a pn junction. This is because the chalcopyrite agent is generally n-doped, the CdS layer 4 being p-doped. This allows the creation of the pn junction needed to establish an electrical current.

This thin CdS layer 4 is itself covered with a tie layer 5, generally formed from what is called intrinsic zinc oxide (ZnO:i).

To form the second electrode, the ZnO:i layer 5 is covered with a layer 6 of TCO (transparent conductive oxide). It may be chosen from the following materials: doped tin oxide, especially doped with fluorine or antimony (the precursors that can be used in the case of CVD deposition may be tin organometallics or halides associated with a fluorine precursor of the hydrofluoric acid or trifluoracetic acid type), doped zinc oxide, especially doped with aluminum (the precursors that can be used in the case of CVD deposition may be zinc and aluminum organometallics or halides) or else doped indium oxide, especially doped with tin (the precursors that can be used in the case of CVD deposition may be tin and indium organometallics or halides). This conductive layer must be as transparent as possible and have a high light transmission over all the wavelengths corresponding to the absorption spectrum of the material constituting the functional layer, so as not to unnecessarily reduce the efficiency of the solar module.

It is observed that the relatively thin (for example 100 nm) dielectric ZnO (ZnO:i) layer 5 between the functional layer 3 and the n-doped conductive layer, for example made of CdS, positively influenced the stability of the process for depositing the functional layer.

The conductive layer 6 has a sheet resistance of at most 30 ohms/□, especially at most 20 ohms/□, preferably at most 10 or 15 ohms/□. It is generally between 5 and 12 ohms/□.

The stack 7 of thin layers is sandwiched between two substrates 1 and 1′ via a lamination interlayer 8, for example made of PU, PVB or EVA. The substrate 1′ differs from the substrate 1 by the fact that it is necessarily made of glass, based on alkali metals (for reasons that were explained in the preamble of the invention), such as a soda-lime-silica glass, so as to form a solar or photovoltaic cell, and then encapsulated peripherally by means of a sealant or sealing resin. An example of the composition of this resin and its methods of use is described in Application EP 739 042.

According to one advantageous feature of the invention (refer to FIG. 2), provision is made to deposit an alkali-metal barrier layer 9 over all or part of the face of the substrate 1′ (for example, at the tin face) that is not in contact with the electrically conductive, in particular molybdenum-based, layer 2. This alkali-metal barrier layer 9 is based on a dielectric, this dielectric being based on silicon nitrides, oxides or oxynitrides, or on aluminum nitrides, oxides or oxynitrides, used alone or as a mixture. The thickness of the barrier layer 9 is between 3 and 200 nm, preferably between 20 and 100 nm, and substantially in the vicinity of 50 nm.

This alkali-metal barrier layer, which is for example based on silicon nitride, may not be stoichiometric. It may be of substoichiometric nature, or even and preferably of superstoichiometric nature. For example, this layer is made of SiₓN_{y}, with an x/y ratio of at least 0.76, preferably between 0.80 and 0.90, since it has been demonstrated that when SiₓN_{y} is rich in Si, the barrier effect to alkali metals is even more effective.

The presence of this barrier layer on the rear face of the substrate 1′ makes it possible to prevent the pollution of the Mo-based conductive layer 2 during the steps of storage (between production and use), when it is in contact with the glass face opposite. It also provides a simple solution for blocking the mechanism for ejection of Na from the rear face of the glass induced by the annealing/selenization steps during which the production racks risk being contaminated, thus causing the drift in the manufacturing processes.

According to one embodiment variant (refer to FIG. 3), provision is made to insert an alkali-metal barrier layer 9′ similar to the previous one between the substrate 1′ that is based on alkali metals and the Mo-based conductive layer 2. Here too it may consist of Si nitrides, oxides or oxynitrides, or of aluminum oxides or oxynitrides. It makes it possible to block the diffusion of Na from the glass toward the upper active layers deposited on the Mo. Although adding an additional step to the manufacturing process, the latter solution offers the possibility of very precisely metering the amount of Na deposited on the Mo layer by using an external source (e.g. NaF, Na₂O₂, Na₂Se). The thickness of the barrier layer is between 3 and 200 nm, preferably between 20 and 100 nm, and substantially in the vicinity of 50 nm.

The barrier layer 9 located on the rear face of the substrate 1′ (in general on the tin-face side of the substrate) is deposited before or after the deposition of Mo-based stacks by magnetron sputtering of the sputter down or sputter up type. An example of this method of implementation is given, for example, in Patent EP 1 179 516. The barrier layer may also be deposited by CVD processes such as PE-CVD (plasma-enhanced chemical vapor deposition).

Among all the possible combinations, the simplest solution is a single-step process, all of the layers are deposited in the same coater.

In this case, the barrier layer based on a dielectric (for example, silicon nitride) is deposited on the rear face by sputter up type magnetron sputtering, whilst the layers based on a conductive material, for example Mo and/or the other barrier layer 9′ made of a dielectric located at the glass (air face) interface and the conductive layer 2, for example based on molybdenum, are then added to the air face by magnetron sputtering of the sputter down type.

Another solution consists in using a process having two separate steps where all the layers are deposited by magnetron sputtering of the sputter down type. In this case, to prevent any contamination of the Mo layer, it is preferable to first deposit the barrier layer on the rear face (i.e. tin-face side of the substrate). Between the two deposition steps, the stack of substrates must be handled in order for it to be turned over.

Whatever the manufacturing process, by referring to FIG. 4 it is observed that with no barrier layer, in particular one made of SiN, the contents of O and of Na are respectively 20 times and 5 times greater than with a 150 nm layer of SiN. It can also be seen that a 50 nm thickness of SiN makes it possible to significantly reduce the diffusion of Na (by a factor of 15 approximately), but that its impermeability with respect to the diffusion of oxygen is limited (factor of 2 approximately). To effectively stop the migration of Na or of oxygen from the glass toward the outside it can be seen that a 150 nm layer of SiN fulfils the role perfectly. The application of such a layer is particularly advantageous during the storage phases to prevent contamination from the face opposite (oxidation of the surface or Na enrichment).

This type of layer is advantageous for preventing the drift in the selenization processes capable of reacting with the Na during the manufacture of the modules. A solar module such as described previously must, in order to be able to operate and deliver an electric voltage to an electrical power distribution system, be, on the one hand, equipped with electrical connection devices and, on the other hand, equipped with support and attachment means that ensure its orientation with respect to the light rays.

1-18. (canceled)

19. A substrate comprising:
an alkali metal,
a first main face comprising at least one surface portion, said first main face comprising a layer of absorbent chalcopyrite material, and
a second main face comprising at least one surface portion, wherein said at least one surface portion of said second main face comprises at least one alkali-metal barrier layer comprising silicon nitride.

20. The substrate as claimed in claim 19, further comprising on said at least one surface portion of the first main face, at least one alkali-metal barrier layer.

21. The substrate as claimed in claim 19, wherein the barrier layer comprises a dielectric.

22. The substrate as claimed in claim 21, wherein the dielectric comprises silicon nitride, silicon oxide or silicon oxynitride, or aluminum nitride, aluminum oxide or aluminum oxynitride, or mixtures thereof.

23. The substrate as claimed in claim 19, wherein the barrier layer comprising silicon nitride is substoichiometric.

24. The substrate as claimed in claim 19, wherein the barrier layer comprising silicon nitride is superstoichiometric.

25. The substrate as claimed in claim 19, wherein the thickness of the barrier layer is between 3 and 200 nm.

26. The substrate as claimed in claim 19, wherein at least one surface portion of the first main face of the substrate comprises a molybdenum-based conductive layer.

27. A stack of substrates comprising at least one substrate as claimed in claim 26, wherein the molybdenum-based conductive layer of the first substrate is in contact with at least one alkali-metal barrier layer comprising silicon nitride on the second main face of a second substrate.

28. An element capable of collecting light comprising at least one substrate as claimed in claim 19.

29. The element capable of collecting light as claimed in claim 28, comprising a first substrate having a glass function and a second substrate having a glass function, said first substrate and said second substrate sandwiched between two electrode-forming conductive layers, wherein at least one of said conductive layers comprises an absorbent agent material, of chalcopyrite type, for converting light energy into electrical energy, wherein at least one of said substrates comprises an alkali metal and has a first main face combined with a layer based on an absorbent agent and a second main face comprising at least one alkali-metal barrier layer.

30. The element as claimed in claim 29, wherein at least one surface portion of the main face of the substrate that is not coated with the barrier layer comprises a molybdenum-based conductive layer.

31. The element as claimed in claim 29, wherein an alkali-metal barrier layer is interposed between the conductive layer and the main face of the substrate.

32. The element as claimed in claim 29, wherein the alkali-metal barrier layer comprises a dielectric.

33. The element as claimed in claim 32, wherein the dielectric comprises silicon nitride, silicon oxide, or silicon oxynitride, or aluminum nitride, aluminum oxide or aluminum oxynitride, or mixtures thereof.

34. The element as claimed in one of claims 29, wherein the thickness of the barrier layer is between 3 and 200 nm.

35. The element as claimed in claim 33, wherein the barrier layer comprises silicon nitride.

36. The element as claimed in claim 35, wherein the layer comprising silicon nitride is substoichiometric.

37. The element as claimed in claim 35, wherein the layer comprising silicon nitride is superstoichiometric.

38. A process for manufacturing a substrate of an element as claimed in claim 29, wherein the barrier layer and the electrically conductive layer or a second barrier layer are deposited using a “sputter up” and “sputter down” magnetron sputtering process.
